(19) United States
(12) Patent Application Publication
(10) Pub. No.: US 2023/0331946 A1
(43) Pub. Date: Oct. 19, 2023

(54) METHOD FOR MANUFACTURING SUBSTRATE MATERIAL FOR SEMICONDUCTOR PACKAGE, PREPREG, AND SUBSTRATE MATERIAL FOR SEMICONDUCTOR PACKAGE

(71) Applicant: Resonac Corporation, Minato-ku, Tokyo (JP)

(72) Inventors: Shunsuke OTAKE, Minato-ku, Tokyo (JP); Kazuyuki MITSUKURA, Minato-ku, Tokyo (JP); Shinji SHIMAOKA, Minato-ku, Tokyo (JP); Hiroaki FUJITA, Minato-ku, Tokyo (JP); Masaki TAKAHASHI, Minato-ku, Tokyo (JP)

(21) Appl. No.: 18/245,347

(22) PCT Filed: Sep. 15, 2021
(86) PCT No.: PCT/JP2021/033973

§ 371 Date: Mar. 15, 2023

(30) Foreign Application Priority Data
Sep. 18, 2020 (WO) PCT/JP2020/035462

(51) Int. Cl. C08J 5/24; H01L 23/498; H01L 21/48; B32B 15/14

(52) U.S. Cl. CPC C08J 5/244; H01L 23/49822; H01L 23/49894; H01L 21/4857; B32B 15/14; C08J 2379/08; C08J 2463/00; B32B 2307/7376; B32B 2457/00; B32B 2260/021; B32B 2260/046

(57) ABSTRACT

A method for manufacturing a substrate material for a semiconductor package, including a step of increasing a temperature of a laminated body in which a metal foil, one or more prepregs, and a metal foil are laminated in this order to a hot-press temperature while pressurizing the laminated body. The prepreg contains an inorganic fiber base material and a thermosetting resin composition. A content of the thermosetting resin composition is 40 to 80% by mass on the basis of a mass of the prepreg. In the step of increasing the temperature of the laminated body to the hot-press temperature while pressurizing the laminated body, the laminated body is heated in a condition in which the lowest melt viscosity of the prepreg is 5000 Pa·s or less.

### TECHNICAL FIELD

The present invention relates to a method for manufacturing a substrate material for a semiconductor package, a prepreg, and a substrate material for a semiconductor package.

### BACKGROUND ART

In order to attain high-speed transmission and downsizing of a semiconductor device, it is required to connect a wiring substrate for a semiconductor package and a semiconductor chip with a high density. As the wiring substrate for a semiconductor package, a wiring substrate having a structure in which different types of semiconductor chips can be connected in parallel by a fine wiring layer, and a wiring substrate having a structure in which a semiconductor chip including a fine bump can be mounted have been proposed.

### CITATION LIST

### Patent Literature

Patent Literature 1: Japanese Unexamined Patent Publication No. H11-126978

Patent Literature 2: Japanese Unexamined Patent Publication No. H8-198982

### SUMMARY OF INVENTION

### Technical Problem

A wiring substrate for a semiconductor package on which a semiconductor chip is mounted is often manufactured by forming wiring on an insulating substrate or a copper foil of a substrate material for a semiconductor package. In general, the substrate material for a semiconductor package is manufactured by a method including heating and pressurizing a laminated body including several laminated prepregs.

In order to attain a high density, the wiring substrate for a semiconductor package may be required to include fine wiring with a width of 10 μm or less. However, in the case of forming such fine wiring, a minute variation in the width of the wiring may be apparent as a non-negligible problem.

An aspect of the present disclosure relates to a substrate material for a semiconductor package that is capable of stably forming fine wiring while suppressing a variation in a wiring width.

### Solution to Problem

An aspect of the present disclosure provides a method for manufacturing a substrate material for a semiconductor package, including: a step of increasing a temperature of a laminated body comprising a metal foil, one or more prepregs, and a metal foil, the metal foils and the prepreg are laminated in this order to a hot-press temperature while pressurizing the laminated body; and a step of heating the laminated body to a temperature higher than or equal to the hot-press temperature while pressurizing the laminated body to form a substrate material including an insulating substrate including the prepreg, and the metal foil provided on both surfaces of the insulating substrate, in this order. The prepreg contains an inorganic fiber base material, and a thermosetting resin composition impregnated in the inorganic fiber base material. A content of the thermosetting resin composition is 40 to 80% by mass on the basis of a mass of the prepreg. In the step of increasing the temperature of the laminated body to the hot-press temperature while pressurizing the laminated body, the laminated body is heated in a heating condition in which the lowest melt viscosity of the prepreg is 5000 Pa·s or less.

In general, the lowest melt viscosity of the prepreg is changed in accordance with the influence of the heating condition such as a temperature increase rate. According to the findings of the present inventors, in the hot-press step for forming the substrate material, when the laminated body including the prepreg having a specific resin content is heated in a condition in which the lowest melt viscosity of the prepreg is 5000 Pa·s or less, a substrate material with an extremely small thickness variation is formed. Then, in the case of forming wiring by using the substrate material with a small thickness variation, a variation in a wiring width is suppressed compared to the related art.

Another aspect of the present disclosure relates to a prepreg containing: an inorganic fiber base material; and a thermosetting resin composition impregnated in the inorganic fiber base material. A content of the thermosetting resin composition is 40 to 80% by mass on the basis of a mass of the prepreg. The lowest melt viscosity of the prepreg measured at a temperature increase rate of 4° C./minute is 5000 Pa·s or less.

By using the prepreg according to another aspect of the present disclosure in the method described above, it is possible to easily manufacture a substrate material for a semiconductor package that is capable of stably forming fine wiring while suppressing a variation in a wiring width.

Still another aspect of the present disclosure provides a substrate material for a semiconductor package, including an insulating substrate including an insulating resin layer, and an inorganic fiber base material provided in the insulating resin layer. A content of the insulating resin layer is 40 to 80% by mass on the basis of a mass of the insulating substrate. A standard deviation of a thickness of the substrate material is 4 μm or less.

Since a thickness variation is small, the substrate material for a semiconductor package according to one aspect of the present disclosure is capable of forming wiring while suppressing a variation in a wiring width.

### ADVANTAGEOUS EFFECTS OF INVENTION

According to an aspect of the present disclosure, the substrate material for a semiconductor package that is capable of stably forming the fine wiring while suppressing the variation in the wiring width is provided. Since the variation in the wiring width is small, it is possible to easily form the fine wiring with a high density. Since the thickness variation is small, the substrate material for a semiconductor package according to one aspect of the present disclosure is capable of easily forming wiring for transmitting a high-frequency signal. The substrate material for a semiconductor package according to an aspect of the present disclosure is also excellent in the reduction of warping. On a wiring substrate including the substrate material for a semiconductor package according to one aspect of the present disclosure, a semiconductor chip including a fine bump can be mounted with high reliability and excellent productivity.

### BRIEF DESCRIPTION OF DRAWINGS

FIG. 1 is a sectional view illustrating an example of a prepreg.

FIG. 2 is a sectional view illustrating an example of a method for manufacturing a substrate material for a semiconductor package.

FIG. 3 is a sectional view illustrating an example of the method for manufacturing the substrate material for a semiconductor package.

FIG. 4 is a graph illustrating an example of a measurement result of a melt viscosity of the prepreg.

### DESCRIPTION OF EMBODIMENTS

The present invention is not limited to the following examples.

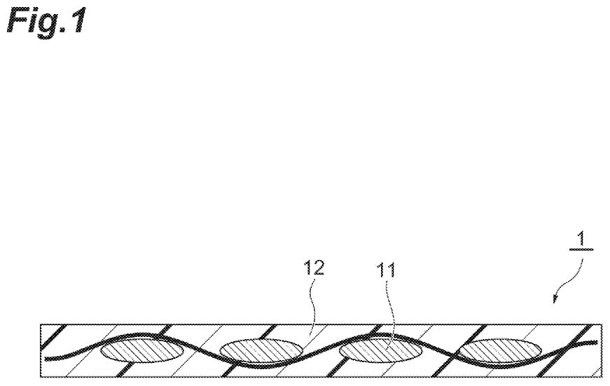

FIG. 1 is a sectional view illustrating an example of a prepreg. A prepreg 1 illustrated in FIG. 1 contains an inorganic fiber base material 11, and a thermosetting resin composition 12 impregnated in the inorganic fiber base material 11.

The inorganic fiber base material 11, for example, can be a woven cloth or a non-woven cloth containing an inorganic fiber. The inorganic fiber configuring the inorganic fiber base material 11 may be a glass fiber, a carbon fiber, or a combination thereof. The inorganic fiber base material 11 may be a glass cloth containing a glass fiber. The ratio of the glass fiber in the inorganic fiber configuring the inorganic fiber base material may be 80 to 100% by mass, 90 to 100% by mass, 95 to 100% by mass, or 99 to 100% by mass. The glass fiber, for example, may be E glass, S glass, or quartz glass. The thickness of the inorganic fiber base material 11 may be 0.01 to 0.20 μm.

The lowest melt viscosity of the prepreg 1 measured at a temperature increase rate of 4° C./minute may be 5000 Pa·s or less. The lowest melt viscosity of the prepreg is the lowest value of a melt viscosity (a complex viscosity) when a test piece of the prepreg is interposed between two parallel plates with a diameter of 8 mm, and dynamic viscoelasticity at a frequency of 10 Hz is measured in a shear mode while increasing the temperature to a temperature of 200° C. or higher from 20° C. at a predetermined temperature increase rate. The thickness of the test piece for measurement is 10 to 400 μm, and as necessary, the test piece is prepared by laminating two or more prepregs. In order for measurement, for example, a viscoelasticity measurement device ARES (manufactured by Rheometric Scientific Far East Ltd.) can be used. The lowest melt viscosity of the prepreg 1 measured at a temperature increase rate of 4° C./minute may be 3000 Pa·s or less, or may be 1000 Pa·s or more.

A temperature at which the prepreg 1 exhibits the lowest melt viscosity may be 80° C. or higher from the viewpoint of the handleability of the prepreg, or may be 120° C. or higher from the viewpoint of preservation stability. The temperature at which the prepreg 1 exhibits the lowest melt viscosity may be 200° C. or lower from the viewpoint of productivity, or may be 180° C. or lower from the viewpoint of reducing warping. As described above, the temperature at which the prepreg 1 exhibits the lowest melt viscosity may be 120° C. to 180° C.

When the melt viscosity of the prepreg 1 measured at a temperature increase rate 4° C./minute decreases to 10000 Pa·s at a temperature T1 [° C.] in accordance with an increase in the temperature of a laminated body 5, and then, increases to 10000 Pa·s at a temperature T2 [° C.] through the lowest melt viscosity, a difference between T1 and T2 may be 20° C. or higher, or 25° C. or higher, and may be 50° C. or lower, from the viewpoint of further suppressing a variation in a wiring width.

When the melt viscosity of the prepreg is measured at a temperature increase rate of 4° C./minute, the prepreg 1 exhibits a melt viscosity that increases to 1000×10³ Pa·s from a point when the lowest melt viscosity is exhibited at a rate of 55×10³ Pa·s/minute or more. Here, the rate is the average value of the increase ratio of the melt viscosity per 1 minute while increasing the melt viscosity to 1000×10³ Pa·s from the point when the lowest melt viscosity is exhibited, and in this specification, may be referred to as a “melt viscosity increase rate”. In a case where a time for increasing the melt viscosity to 1000×10³ Pa·s from the point when the lowest melt viscosity [Pa·s] is exhibited is T minutes, the melt viscosity increase rate is calculated by the following expression.

Melt Viscosity Increase Rate [Pa·s/minute]=(1000×10³−Lowest Melt Viscosity)/T

From the viewpoint of further suppressing the variation in the wiring width, the melt viscosity increase rate may be 60×10³ Pa·s/minute or more, 65×10³ Pa·s/minute or more, 70×10³ Pa·s/minute or more, 75×10³ Pa·s/minute or more, 80×10³ Pa·s/minute or more, 85×10³ Pa·s/minute or more, 90×10³ Pa·s/minute or more, 95×10³ Pa·s/minute or more, 100×10³ Pa·s/minute or more, 105×10³ Pa·s/minute or more, or 110×10³ Pa·s/minute or more, and may be 200×10³ Pa·s/minute or less, 190×10³ Pa·s/minute or less, 180×10³ Pa·s/minute or less, 170×10³ Pa·s/minute or less, or 160×10³ Pa·s/minute or less.

The content of the thermosetting resin composition 12 in the prepreg 1 may be 40 to 80% by mass. By using the prepreg containing the thermosetting resin composition 12 at a ratio of 40 to 80% by mass, it is possible to easily manufacture a substrate material for a semiconductor package with a small thickness variation by the following method. The content of the thermosetting resin composition 12, for example, can be adjusted in accordance with a coating amount of the curable resin composition according to the thickness of the inorganic fiber base material 11.

The content of the thermosetting resin composition 12 in the prepreg 1, for example, can be obtained by a method including dividing the region of the inorganic fiber base material 11 and the region of the thermosetting resin composition 12 in the sectional picture of the prepreg 1 by binarization processing, and calculating each area. In this case, the density of the inorganic fiber base material 11 may be regarded as the same as the density of the thermosetting resin composition 12.

The thermosetting resin composition 12 may contain an inorganic component, in addition to a thermosetting resin component. The ratio of the resin component in the thermosetting resin composition 12 may be 20 to 100% by mass with respect to the mass of the thermosetting resin composition 12, may be 20 to 80% by mass from the viewpoint of reducing a linear coefficient of expansion, may be 30 to 100% by mass from the viewpoint of reducing voids after lamination, or may be 40 to 100% by mass from the viewpoint of further improving the flatness of the substrate material. As described above, the ratio of the resin component in the thermosetting resin composition 12 may be 40 to 80% by mass with respect to the mass of the thermosetting resin composition 12. That is, the ratio of the resin component in the prepreg 1 may be 16 to 64% by mass.

The ratio of the resin component contained in the thermosetting resin composition 12 can be calculated by a method such as ash content measurement. The ash content measurement is a method for calculating the ratio of the resin component by carbonizing the resin component at a high temperature.

In the thermosetting resin composition 12, components other than the inorganic component may be regarded as the resin component. An example of the inorganic component is an inorganic filler. In the thermosetting resin composition 12, components other than the inorganic filler may be regarded as the resin component.

The lowest melt viscosity of the prepreg 1 can be controlled by the resin component. The lowest melt viscosity is not particularly limited, and for example, can be controlled by adjusting the ratio of the resin component and the inorganic component, the molecular weight and the glass transition temperature of a high-molecular-weight component contained in the resin component, the type and the blending ratio of a thermosetting resin, and the type and the blending ratio of a curing accelerator.

In particular, the behavior of the melt viscosity of the prepreg can be greatly affected by the molecular weight and the glass transition temperature of the high-molecular-weight component contained in the resin component, and the type and the blending ratio of the curing accelerator. For example, the glass transition temperature of the high-molecular-weight component may be lower than a temperature at which a curing reaction of the thermosetting resin composition is activated. The glass transition temperature of the high-molecular-weight component may be a temperature indicating the maximum value of tanδ when the dynamic viscoelasticity of a strip-shaped molded body of the high-molecular-weight component is measured in a temperature range of 40° C. to 350° C. in a condition where a distance between chucks is 20 mm, a frequency is 10 Hz, and a temperature increase rate is 5° C./minute. In order to measure the dynamic viscoelasticity, for example, a dynamic viscoelasticity measurement device manufactured by UBM can be used. The temperature at which the curing reaction of the thermosetting resin composition is activated, for example, may be a temperature at which a heat release amount according to the curing reaction is the maximum value when the differential scanning calorimetry of the thermosetting resin composition is performed in a temperature range of 40° C. to 350° C. at a temperature increase rate of 5° C./minute. In order for differential scanning calorimetry, for example, a differential scanning calorimeter manufactured by PerkinElmer, Inc. can be used.

The glass transition temperature of the high-molecular-weight component may be 10° C. to 80° C. lower than the temperature at which the curing reaction of the thermosetting resin composition is activated. From the viewpoint of being capable of reducing the influence due to a temperature variation when laminating the prepreg, the glass transition temperature of the high-molecular-weight component may be 20° C. to 80° C. lower than the temperature at which the curing reaction of the thermosetting resin composition is activated. From the viewpoint of being capable of suppressing the voids when laminating the prepreg, the glass transition temperature of the high-molecular-weight component may be 10° C. to 60° C. lower than the temperature at which the curing reaction of the thermosetting resin composition is activated. As described above, the glass transition temperature of the high-molecular-weight component may be 20° C. to 60° C. lower than the temperature at which the curing reaction of the thermosetting resin composition is activated.

The thermosetting resin composition 12 may contain a thermoplastic resin, as the high-molecular-weight component. The thermoplastic resin is not particularly limited insofar as the resin is softened by heating, and may have one or more types of reactive functional groups on a molecular end or in a molecular chain. Examples of the reactive functional group include an epoxy group, a hydroxyl group, a carboxyl group, an amino group, an amide group, an isocyanate group, an acryloyl group, a methacryloyl group, a vinyl group, and a maleic anhydride group.

The thermoplastic resin, for example, may be at least one type selected from an acrylic resin, a polyamide resin, a polyimide resin, and a polyurethane resin.

The content of the thermoplastic resin, for example, may be 20 to 80% by mass on the basis of the total mass of the components other than the inorganic filler in the thermosetting resin composition 12.

From the viewpoint of suppressing moisture absorption, the thermoplastic resin may include a resin having a siloxane group. For example, an acrylic resin, a polyamide resin, a polyimide resin, or a polyurethane resin may have a siloxane group. The resin having a siloxane group may be a silicone resin.

From the viewpoint of suppressing outgassing during heating and bonding adhesiveness, the thermoplastic resin may include a polyimide resin having a siloxane group. The polyimide resin having a siloxane group, for example, may be a polymer generated by a reaction between siloxane diamine and a tetracarboxylic dianhydride, or a polymer generated by a reaction between siloxane diamine and bismaleimide.

The siloxane diamine, for example, may be a compound represented by General Formula (5) described below.

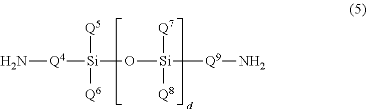

In the formula, Q⁴ and Q⁹ each independently represent an alkylene group having 1 to 5 carbon atoms or a phenylene group that may have a substituent, Q⁵, Q⁶, Q⁷, and Q⁸ each independently represent an alkyl group having 1 to 5 carbon atoms, a phenyl group, or a phenoxy group, and d represents an integer of 1 to 5.

Examples of siloxane diamine represented by Formula (5), in which d is 1, include 1,1,3,3-tetramethyl-1,3-bis(4-aminophenyl) disiloxane, 1,1,3,3-tetraphenoxy-1,3-bis(4-aminoethyl) disiloxane, 1,1,3,3-tetraphenyl-1,3-bis(2-aminoethyl) disiloxane, 1,1,3,3-tetraphenyl-1,3-bis(3-aminopropyl) disiloxane, 1,1,3,3-tetramethyl-1,3-bis(2-aminoethyl) disiloxane, 1,1,3,3-tetramethyl-1,3-bis(3-aminopropyl) disiloxane, 1,1,3,3-tetramethyl-1,3-bis(3-aminobutyl) disiloxane, and 1,3-dimethyl-1,3-dimethoxy-1,3-bis(4-aminobutyl) disiloxane. Examples of siloxane diamine represented by Formula (5), in which d is 2, include 1,1,3,3,5,5-hexamethyl-1,5-bis(4-aminophenyl) trisiloxane, 1,1,5,5-tetraphenyl-3,3-dimethyl-1,5-bis(3-aminopropyl) trisiloxane, 1,1,5,5-tetraphenyl-3,3-dimethoxy-1,5-bis(4-aminobutyl) trisiloxane, 1,1,5,5-tetraphenyl-3,3-dimethoxy-1,5-bis(5-aminopentyl) trisiloxane, 1,1,5,5-tetramethyl-3,3-dimethoxy-1,5-bis(2-aminoethyl) trisiloxane, 1,1,5,5-tetramethyl-3,3-dimethoxy-1,5-bis(4-aminobutyl) trisiloxane, 1,1,5,5-tetramethyl-3,3-dimethoxy-1,5-bis(5-aminopentyl) trisiloxane, 1,1,3,3,5,5-hexamethyl-1,5-bis(3-aminopropyl) trisiloxane, 1,1,3,3,5,5-hexaethyl-1,5 -bis(3-aminopropyl) trisiloxane, and 1,1,3,3,5,5-hexapropyl-1,5-bis(3-aminopropyl) trisiloxane.

Examples of a commercially available product of the siloxane diamine include “PAM-E” (an amino group equivalent of 130 g/mol), “KF-8010” (an amino group equivalent of 430 g/mol), “X-22-161A” (an amino group equivalent of 800 g/mol), “X-22-161B” (an amino group equivalent of 1500 g/mol), “KF-8012” (an amino group equivalent of 2200 g/mol), “KF-8008” (an amino group equivalent of 5700 g/mol), “X-22-9409” (an amino group equivalent of 700 g/mol, a side-chain phenyl type), and “X-22-1660B-3” (an amino group equivalent of 2200 g/mol, a side-chain phenyl type) (all are manufactured by Shin-Etsu Chemical Co., Ltd.), and “BY-16-853U” (an amino group equivalent of 460 g/mol), “BY-16-853” (an amino group equivalent of 650 g/mol), and “BY-16-853B” (an amino group equivalent of 2200 g/mol) (all are manufactured by Dow Corning Toray Co., Ltd.), which have an amino group on both ends. Only one type of the commercially available products can be used, or two or more types thereof can be used by being mixed. Among them, from the viewpoint of reactivity with respect to a maleimide group, the siloxane diamine may be selected from “PAM-E”, “KF-8010”, “X-22-161A”, “X-22-161B”, “BY-16-853U”, and “BY-16-853”. From the viewpoint of dielectric properties, the siloxane diamine may be selected from “PAM-E”, “KF-8010”, “X-22-161A”, “BY-16-853U”, and “BY-16-853”. From the viewpoint of the compatibility of a varnish, the siloxane diamine may be selected from “KF-8010”, “X-22-161A”, and “BY-16-10 853”.

The content of the siloxane group in the polyimide resin having a siloxane group is not particularly limited, and may be 5 to 50% by mass on the basis of the mass of the polyimide resin, from the viewpoint of the reactivity and the compatibility. The content of the siloxane group may be 5 to 30% by mass from the viewpoint of heat resistance, or may be 10 to 30% by mass from the viewpoint of being capable of further reducing a moisture absorption rate.

The polyimide resin may be a polymer that is synthesized from diamine other than the siloxane diamine, or may be a polymer that is synthesized from a combination of the siloxane diamine and the other diamine.

The other diamine that is used as the raw material of the polyimide resin is not particularly limited, and examples thereof include aromatic diamine such as o-phenylene diamine, m-phenylene diamine, p-phenylene diamine, 3,3′-diaminodiphenyl ether, 3,4′-diaminodiphenyl ether, 4,4′-diaminodiphenyl ether, 3,3′-diaminodiphenyl methane, 3,4′-diaminodiphenyl methane, 4,4′-diaminodiphenyl ether methane, bis(4-amino-3,5-dimethyl phenyl) methane, bis(4-amino-3,5-diisopropyl phenyl) methane, 3,3′-diaminodiphenyl difluoromethane, 3,4′-diaminodiphenyl difluoromethane, 4,4′-diaminodiphenyl difluoromethane, 3,3′-diaminodiphenyl sulfone, 3,4′-diaminodiphenyl sulfone, 4,4′-diaminodiphenyl sulfone, 3,3′-diaminodiphenyl sulfide, 3,4′-diaminodiphenyl sulfide, 4,4′-diaminodiphenyl sulfide, 3,3′-diaminodiphenyl ketone, 3,4′-diaminodiphenyl ketone, 4,4′-diaminodiphenyl ketone, 2,2-bis(3-aminophenyl) propane, 2,2′-(3,4′-diaminodiphenyl) propane, 2,2-bis(4-aminophenyl) propane, 2,2-bis(3-aminophenyl) hexafluoropropane, 2,2-(3,4′-diaminodiphenyl) hexafluoropropane, 2,2-bis(4-aminophenyl) hexafluoropropane, 1,3-bis(3-aminophenoxy) benzene, 1,4-bis(3-aminophenoxy) benzene, 1,4-bis(4-aminophenoxy) benzene, 3,3′-(1,4-phenylene bis(1-methyl ethylidene)) bisaniline, 3,4′-(1,4-phenylene bis(1-methyl ethylidene)) bisaniline, 4,4′-(1,4-phenylene bis(1-methyl ethylidene)) bisaniline, 2,2-bis(4-(3 -aminophenoxy)phenyl) propane, 2,2-bis(4-(3-aminophenoxy)phenyl) hexafluoropropane, 2,2-bis(4-(4-aminophenoxy)phenyl) hexafluoropropane, bis(4-(3-aminophenoxy)phenyl) sulfide, bis(4-(4-aminophenoxy)phenyl) sulfide, bis(4-(3-aminophenoxy)phenyl) sulfone, bis(4-(4-aminophenoxy)phenyl) sulfone, 3,3′-dihydroxy-4,4′-diaminobiphenyl, and a 3,5-diaminobenzoic acid, 1,3-bis(aminomethyl) cyclohexane, 2,2-bis(4-aminophenoxyphenyl) propane, aliphatic ether diamine represented by General Formula (4) described below, aliphatic diamine represented by General Formula (11) described below, and diamine having a carboxyl group and/or a hydroxyl group.

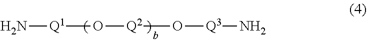

In Formula (4), Q¹, Q², and Q³ each independently represent an alkylene group having 1 to 10 carbon atoms, and b represents an integer of 2 to 80.

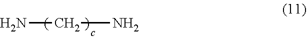

In Formula (11), c represents an integer of 5 to 20.

Examples of the aliphatic ether diamine represented by General Formula (4) described above include aliphatic diamine represented by the following general formula;

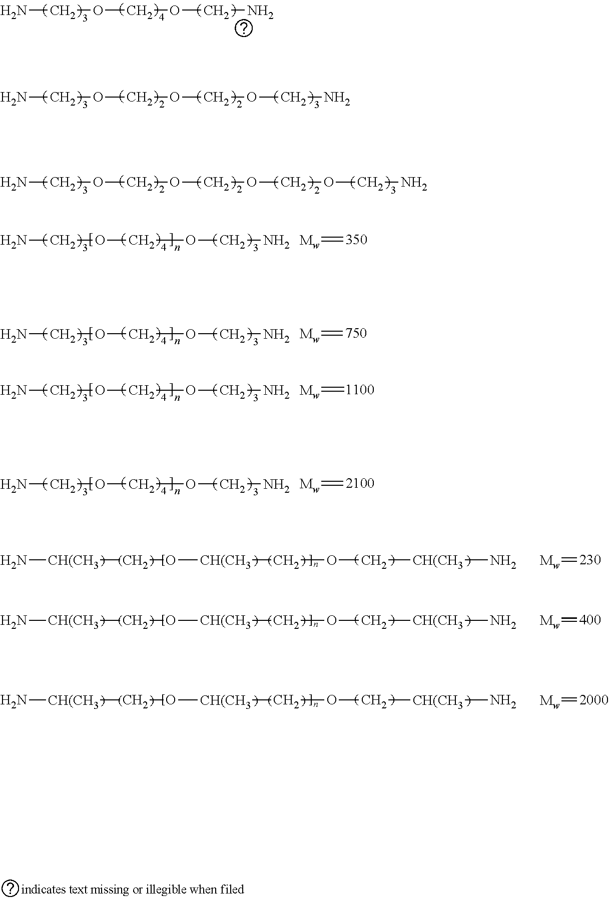

and aliphatic ether diamine represented by General Formula (12) described below.

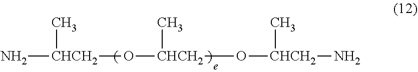

In Formula (12), e represents an integer of 0 to 80.

Examples of the aliphatic diamine represented by General Formula (11) described above include 1,2-diaminoethane, 1,3-diaminopropane, 1,4-diaminobutane, 1,5-diaminopentane, 1,6-diaminohexane, 1,7-diaminoheptane, 1,8-diaminooctane, 1,9-diaminononane, 1,10-diaminodecane, 1,11-diaminoundecane, 1,12-diaminododecane, and 1,2-diaminocyclohexane.

Only one type of the diamines exemplified as described above can be used, or two or more types thereof can be used in combination.

A tetracarboxylic dianhydride can be used as the raw material of the polyimide resin. Examples of the tetracarboxylic dianhydride include a pyromellitic dianhydride, a 3,3′,4,4′-biphenyl tetracarboxylic dianhydride, a 2,2′,3,3′-biphenyl tetracarboxylic dianhydride, a 2,2-bis(3,4-dicarboxyphenyl) propane dianhydride, a 2,2-bis(2,3-dicarboxyphenyl) propane dianhydride, a 1,1-bis(2,3-dicarboxyphenyl) ethane dianhydride, a 1,1-bis(3,4-dicarboxyphenyl) ethane dianhydride, a bis(2,3-dicarboxyphenyl) methane dianhydride, a bis(3,4-dicarboxyphenyl) methane dianhydride, a bis(3,4-dicarboxyphenyl) sulfone dianhydride, a 3,4,9,10-perylene tetracarboxylic dianhydride, a bis(3,4-dicarboxyphenyl) ether dianhydride, a benzene-1,2,3,4-tetracarboxylic dianhydride, a 3,4,3′,4′-benzophenone tetracarboxylic dianhydride, a 2,3,2′,3′-benzophenone tetracarboxylic dianhydride, a 3,3,3′,4′-benzophenone tetracarboxylic dianhydride, a 1,2,5,6-naphthalene tetracarboxylic dianhydride, a 1,4,5,8-naphthalene tetracarboxylic dianhydride, a 2,3,6,7-naphthalene tetracarboxylic dianhydride, a 1,2,4,5-naphthalene tetracarboxylic dianhydride, a 2,6-dichloronaphthalene-1,4,5,8-tetracarboxylic dianhydride, a 2,7-dichloronaphthalene-1,4,5,8-tetracarboxylic dianhydride, a 2,3,6,7-tetrachloronaphthalene-1,4,5,8-tetracarboxylic dianhydride, a phenanthrene-1,8,9,10-tetracarboxylic dianhydride, a pyrazine-2,3,5,6-tetracarboxylic dianhydride, a thiophene-2,3,5,6-tetracarboxylic dianhydride, a 2,3,3′,4′-biphenyl tetracarboxylic dianhydride, a 3,4,3′,4′-biphenyl tetracarboxylic dianhydride, a 2,3,2′,3′-biphenyl tetracarboxylic dianhydride, a bis(3,4-dicarboxyphenyl) dimethyl silane dianhydride, a bis(3,4-dicarboxyphenyl) methyl phenyl silane dianhydride, a bis(3,4-dicarboxyphenyl) diphenyl silane dianhydride, a 1,4-bis(3,4-dicarboxyphenyl dimethyl silyl) benzene dianhydride, a 1,3-bis(3,4-dicarboxyphenyl)-1,1,3,3-tetramethyl dicyclohexane dianhydride, a p-phenylene bis(trimellitate anhydride), an ethylene tetracarboxylic dianhydride, a 1,2,3,4-butane tetracarboxylic dianhydride, a decahydronaphthalene-1,4,5,8-tetracarboxylic dianhydride, a 4,8-dimethyl-1,2,3,5,6,7-hexahydronaphthalene-1,2,5,6-tetracarboxylic dianhydride, a cyclopentane-1,2,3,4-tetracarboxylic dianhydride, a pyrrolidine-2,3,4,5-tetracarboxylic dianhydride, a 1,2,3,4-cyclobutane tetracarboxylic dianhydride, a bis(exo-bicyclo[2,2,1]heptane-2,3-dicarboxylic dianhydride, a bicyclo-[2,2,2]-ortho-7-ene-2,3,5,6-tetracarboxylic dianhydride, a 2,2-bis(3,4-dicarboxyphenyl) propane dianhydride, a 2,2-bis[4-(3,4-dicarboxyphenyl) phenyl] propane dianhydride, a 2,2-bis(3,4-dicarboxyphenyl) hexafluoropropane dianhydride, a 2,2-bis [4-(3,4-dicarboxyphenyl) phenyl] hexafluoropropane dianhydride, a 4,4′-bis(3,4-dicarboxyphenoxy)diphenyl sulfide dianhydride, a 1,4-bis(2-hydroxyhexafluoroisopropyl) benzene bis(trimellitic anhydride), a 1,3-bis(2-hydroxyhexafluoroisopropyl) benzene bis(trimellitic anhydride), a 5-(2,5-dioxotetrahydrofuryl)-3-methyl-3-cyclohexene-1,2-dicarboxylic dianhydride, a tetrahydrofuran-2,3,4,5-tetracarboxylic dianhydride, and a tetracarboxylic dianhydride represented by General Formula (7) described below.

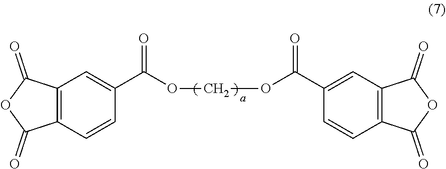

In Formula (7), a represents an integer of 2 to 20.

The tetracarboxylic dianhydride represented by General Formula (7) described above can be synthesized from trimellitic anhydride monochloride and the corresponding diol, and specifically, examples thereof include a 1,2-(ethylene) bis(trimellitate anhydride), a 1,3-(trimethylene) bis(trimellitate anhydride), a 1,4-(tetramethylene) bis(trimellitate anhydride), a 1,5-(pentamethylene) bis(trimellitate anhydride), a 1,6-(hexamethylene) bis(trimellitate anhydride), a 1,7-(heptamethylene) bis(trimellitate anhydride), a 1,8-(octamethylene) bis(trimellitate anhydride), a 1,9-(nonamethylene) bis(trimellitate anhydride), a 1,10-(decamethylene) bis(trimellitate anhydride), a 1,12-(dodecamethylene) bis(trimellitate anhydride), a 1,16-(hexadecamethylene) bis(trimellitate anhydride), and a 1,18-(octadecamethylene) bis(trimellitate anhydride).

The tetracarboxylic dianhydride may include a tetracarboxylic dianhydride represented by General Formula (6) or (8) described below, from the viewpoint of imparting excellent solubility with respect to a solvent and moisture resistance reliability.

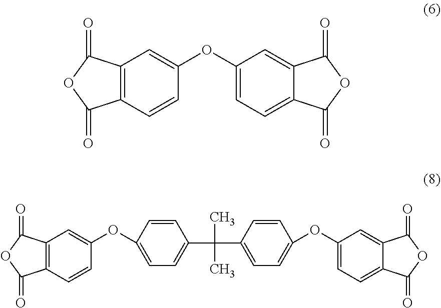

Only one type of the tetracarboxylic dianhydrides as described above can be used, or two or more types thereof can be used in combination.

Bismaleimide can be used as the raw material of the polyimide resin. The bismaleimide is not particularly limited, and examples thereof include bis(4-maleimide phenyl) methane, polyphenyl methane maleimide, bis(4-maleimide phenyl) ether, bis(4-maleimide phenyl) sulfone, 3,3-dimethyl-5,5-diethyl-4,4-diphenyl methane bismaleimide, 4-methyl-1,3-phenylene bismaleimide, m-phenylene bismaleimide, and 2,2-bis(4-(4-maleimide phenoxy)phenyl) propane. Only one type of the bismaleimides can be used, or two or more types thereof can be used by being mixed. The bismaleimide may be selected from the bis(4-maleimide phenyl) methane, the bis(4-maleimide phenyl) sulfone, the 3,3-dimethyl-5,5-diethyl-4,4-diphenyl methane bismaleimide, and the 2,2-bis(4-(4-maleimide phenoxy)phenyl) propane, which have high reactivity and are capable of further improving the dielectric properties and wiring properties, or may be selected from the 3,3-dimethyl-5,5-diethyl-4,4-diphenyl methane bismaleimide, the bis(4-maleimide phenyl) methane, and the 2,2-bis(4-(4-maleimide phenoxy)phenyl) propane from the viewpoint of the solubility with respect to the solvent, and the bis(4-maleimide phenyl) methane may be selected from the viewpoint of a low price, or the 2,2-bis(4-(4-maleimide phenoxy)phenyl) propane and BMI-3000 (Product Name) manufactured by Designer Molecules Inc. may be selected from the viewpoint of the wiring properties.

The thermosetting resin composition 12 contains a thermosetting resin that is a compound for forming a cross-linked polymer by heating. In general, the thermosetting resin has a reactive functional group that causes a cross-linking reaction. The reactive functional group, for example, may be an epoxy group, a hydroxyl group, a carboxyl group, an amino group, an amide group, an isocyanate group, an acryloyl group, a methacryloyl group, a vinyl group, a maleic anhydride group, or a combination thereof.

The content of the thermosetting resin, for example, may be 20 to 80% by mass on the basis of the total mass of the components other than the inorganic filler in the thermosetting resin composition 12.

The thermosetting resin composition 12 may contain an epoxy resin, as the thermosetting resin. The epoxy resin may be a compound having two or more epoxy groups. The epoxy resin may be a phenolic glycidyl ether type epoxy resin from the viewpoint of curability and the properties of a cured material. Examples of the phenolic glycidyl ether type epoxy resin include a biphenyl aralkyl type epoxy resin, bisphenol A type (or AD type, S type, and F type) glycidyl ether, hydrogenated bisphenol A type glycidyl ether, ethylene oxide adduct-bisphenol A type glycidyl ether, propylene oxide adduct-bisphenol A type glycidyl ether, glycidyl ether of a phenol novolac resin, glycidyl ether of a cresol novolac resin, glycidyl ether of a bisphenol A novolac resin, glycidyl ether of a naphthalene resin, trifunctional (or tetrafunctional) glycidyl ether, and glycidyl ether of a dicyclopentadiene phenol resin. Other examples of the epoxy resin include glycidyl ester of a dimer acid, trifunctional (or tetrafunctional) glycidyl amine, glycidyl amine of a naphthalene resin, and the like. Only one type of the epoxy resins can be used, or two or more types thereof can be used in combination.

The thermosetting resin composition 12 may contain an acrylate compound, as the thermosetting resin. The acrylate compound may have two or more (meth)acryloyl groups. Examples of the acrylate compound include diethylene glycol diacrylate, triethylene glycol diacrylate, tetraethylene glycol diacrylate, diethylene glycol dimethacrylate, triethylene glycol dimethacrylate, tetraethylene glycol dimethacrylate, trimethylol propane diacrylate, trimethylol propane triacrylate, trimethylol propane dimethacrylate, trimethylol propane trimethacrylate, 1,4-butanediol diacrylate, 1,6-hexanediol diacrylate, 1,4-butanediol dimethacrylate, 1,6-hexanediol dimethacrylate, pentaerythritol triacrylate, pentaerythritol tetraacrylate, pentaerythritol trimethacrylate, pentaerythritol tetramethacrylate, dipentaerythritol hexaacrylate, dipentaerythritol hexamethacrylate, 2-hydroxyethyl acrylate, 2-hydroxyethyl methacrylate, 1,3-acryloyl oxy-2-hydroxypropane, 1,2-methacryloyl oxy-2-hydroxypropane, methylene bisacrylamide, N,N-dimethyl acrylamide, N-methylol acrylamide, triacrylate of tris(β-hydroxyethyl) isocyanurate, a compound represented by General Formula (13) described below, urethane acrylate or urethane methacrylate, and urea acrylate.

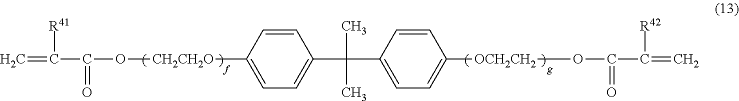

In Formula (13), R⁴¹ and R⁴² each independently represent a hydrogen atom or a methyl group, and f and g each independently represent an integer of 1 or more. As represented by Formula (13), a radiation polymerizable compound having a glycol skeleton is capable of imparting solvent resistance after curing. The urethane acrylate, the urethane methacrylate, and isocyanuric acid-modified di/triacrylate and methacrylate are capable of imparting high bonding adhesiveness after curing.

The thermosetting resin composition 12 may contain a thermosetting elastomer selected from a styrene-based elastomer, an olefin-based elastomer, an urethane-based elastomer, a polyester-based elastomer, a polyamide-based elastomer, an acrylic elastomer, and a silicone-based elastomer, as the thermosetting resin. The thermosetting elastomer contains a hard segment component and a soft segment component, and in general, the hard segment component contributes to heat resistance and strength, and the soft segment component contributes to flexibility and toughness. Only one type of the thermosetting elastomers can be used, or two or more types thereof can be used by being mixed. The thermosetting elastomer may be selected from the styrene-based elastomer, the olefin-based elastomer, the polyamide-based elastomer, and the silicone-based elastomer from the viewpoint of the heat resistance and insulating reliability, or may be selected from the styrene-based elastomer and the olefin-based elastomer from the viewpoint of the dielectric properties.

The thermosetting elastomer has a reactive functional group on a molecular end or in a molecular chain. Examples of the reactive functional group include an epoxy group, a hydroxyl group, a carboxyl group, an amino group, an amide group, an isocyanate group, an acryloyl group, a methacryloyl group, a vinyl group, and a maleic anhydride group. The reactive functional group of the thermosetting elastomer may be the epoxy group, the amino group, the acryloyl group, the methacryloyl group, vinyl group, or the maleic anhydride group, or may be the epoxy group, the amino group, or the maleic anhydride group, from the viewpoint of the compatibility, the wiring properties, and the like. The content of the thermosetting elastomer may be 10 to 70% by mass on the basis of the mass of the thermosetting resin composition, or may be 20 to 60% by mass from the viewpoint of the dielectric properties and the compatibility of the varnish.

The thermosetting resin composition, as necessary, may contain a curing accelerator for accelerating the curing reaction of the thermosetting resin. Examples of the curing accelerator include a peroxide, an imidazole compound, an organic phosphorus-based compound, secondary amine, tertiary amine, and a quaternary ammonium salt. Only one type of the curing accelerators can be used, or two or more types thereof can be used in combination. In a case where the thermosetting resin is the epoxy resin, the curing accelerator, may be, for example, the imidazole compound.

The content of the curing accelerator may be 0.1 to 10% by mass on the basis of the total mass of the components other than the inorganic filler in the thermosetting resin composition, or may be 0.5 to 5% by mass, or 0.75 to 3% by mass from the viewpoint of the dielectric properties and the handleability of the prepreg.

The thermosetting resin composition 12 may contain a cohesion aid. Examples of the cohesion aid include a silane coupling agent, a triazole compound, and a tetrazole compound.

In order to improve cohesiveness with a metal, the silane coupling agent may be a compound having a nitrogen atom. Examples of the silane coupling agent include N-2-(aminoethyl)-3-aminopropyl methyl dimethoxysilane, N-2-(aminoethyl)-3-aminopropyl trimethoxysilane, 3-aminopropyl trimethoxysilane, 3-aminopropyl triethoxysilane, 3-triethoxysilyl-N-(1,3-dimethyl-butylidene) propyl amine, N-phenyl-3-aminopropyl trimethoxysilane, tris-(trimethoxysilyl propyl) isocyanurate, 3-ureidopropyl trialkoxysilane, and 3-isocyanate propyl triethoxysilane.

The content of the silane coupling agent may be 0.1 to 20% by mass on the basis of the total mass of the components other than the inorganic filler in the thermosetting resin composition 12, from the viewpoint of an addition effect, the heat resistance, a manufacturing cost, and the like.

Examples of the triazole compound include 2-(2′-hydroxy-5′-methyl phenyl) benzotriazole, 2-(2′-hydroxy-3′-tert-butyl-5′-methyl phenyl)-5-chlorobenzotriazole, 2-(2′-hydroxy-3′,5′-di-tert-amyl phenyl) benzotriazole, 2-(2′-hydroxy-5′-tert-octyl phenyl) benzotriazole, 2,2′-methylene bis[6-(2H-benzotriazol-2-yl)-4-tert-octyl phenol], 6-(2-benzotriazolyl)-4-tert-octyl-6′-tert-butyl-4′-methyl-2,2′-methylene bisphenol, 1,2,3-benzotriazole, 1-[N,N-bis(2-ethyl hexyl) aminomethyl] benzotriazole, carboxybenzotriazole, 1-[N,N-bis(2-ethyl hexyl) aminomethyl] methyl benzotriazole, and 2,2′-[[(methyl-1H-benzotriazol-1-yl) methyl] imino] bisethanol.

Examples of the tetrazole compound include 1H-tetrazole, 5-amino-1H-tetrazole, 5-methyl-1H-tetrazole, 5-phenyl-1H-tetrazole, 1-methyl-5-ethyl-1H-tetrazole, 1-methyl-5-mercapto-1H-tetrazole, 1-phenyl-5-mercapto-1H-tetrazole, 1-(2-dimethyl aminoethyl)-5-mercapto-1H-tetrazole, 2-methoxy-5-(5 -trifluoromethyl-1H-tetrazol-1-yl)-benzaldehyde, 4,5-di(5-tetrazolyl)-[1,2,3] triazole, and 1-methyl-5-benzoyl-1H-tetrazole.

The content of the triazole compound and the tetrazole compound may be 0.1 to 20% by mass on the basis of the total mass of the components other than the inorganic filler in the thermosetting resin composition 12, from the viewpoint of the addition effect, the heat resistance, and the manufacturing cost.

Each of the silane coupling agents, the triazole compounds, and the tetrazole compounds may be used alone, or may be used together.

The thermosetting resin composition 12 may contain an ion scavenger. By adsorbing ionic impurities in an organic insulating layer with the ion scavenger, it is possible to improve the insulating reliability during the moisture absorption. Examples of the ion scavenger include a compound known as a copper inhibitor for preventing copper from being ionized and eluted, such as a triazine thiol compound and a phenolic reductant, and a bismuth-based compound, an antimony-based compound, a magnesium-based compound, an aluminum-based compound, a zirconium-based compound, a calcium-based compound, a titanium-based compound, a tin-based compound, or a mixed inorganic compound thereof.

Examples of a commercially available product of the ion scavenger include inorganic ion scavengers (Product Name: IXE-300 (an antimony-based ion scavenger), IXE-500 (a bismuth-based ion scavenger), IXE-600 (a mixed ion scavenger of antimony and bismuth), IXE-700 (a mixed ion scavenger of magnesium and aluminum), IXE-800 (a zirconium-based ion scavenger), and IXE-1100 (a calcium-based ion scavenger)), manufactured by TOAGOSEI CO., LTD. Only one type of the inorganic ion scavengers may be used, or two or more types thereof may be used by being mixed.

The content of the ion scavenger may be 0.01 to 10% by mass on the basis of the total mass of the components other than the inorganic filler in the thermosetting resin composition 12, from the viewpoint of the addition effect, the heat resistance, the manufacturing cost, and the like.

In order to impart low moisture absorbency and low moisture permeability, the thermosetting resin composition 12 may contain a filler. The filler may be an inorganic filler, an organic filler, or a combination thereof. The inorganic filler can be added in order to impart heat conductivity, low thermally expandability, low moisture absorbency, and the like to an insulating substrate. The organic filler can be added in order to impart toughness and the like to the insulating substrate.

Examples of the inorganic filler include alumina, aluminum hydroxide, magnesium hydroxide, calcium carbonate, magnesium carbonate, calcium silicate, magnesium silicate, calcium oxide, magnesium oxide, aluminum oxide, aluminum nitride, crystalline silica, amorphous silica, boron nitride, titania, glass, iron oxide, ceramic, and carbon. Examples of the organic filler include a rubber-based filler. Only one type of the inorganic fillers or the organic fillers can be used, or two or more types thereof can be used in combination. The thermosetting resin composition 12 may contain a silica filler and/or an alumina filler.

The average particle diameter of the filler may be 10 μm or less, or 5 μm or less. The maximum particle diameter of the filler may be 30 μm or less, or 20 μm or less. In a case where the average particle diameter is greater than 10 μm and the maximum particle diameter is greater than 30 μm, it tends to be difficult to obtain the effect of improving fracture toughness. The lower limit of the average particle diameter and the maximum particle diameter is not particularly limited, and is generally 0.001 μm.

The filler may satisfy both of the average particle diameter of 10 μm or less and the maximum particle diameter of 30 μm or less. A filler of which the maximum particle diameter is 30 μm or less but the average particle diameter is greater than 10 μm tends to relatively reduce bonding adhesive strength. A filler of which the average particle diameter is 10 μm or less but the maximum particle diameter is greater than 30 μm tends to increase a variation in the bonding adhesive strength.

By using a scanning electron microscope (SEM), it is possible to measure the average particle diameter and the maximum particle diameter of the filler, for example, by a method for measuring the particle diameter of fillers. In the case of the measurement method using SEM, for example, a cured material obtained by heating and curing the thermosetting resin composition is prepared, and the sectional surface of the central portion of the cured material may be observed with SEM. The existence probability of the fillers with a particle diameter of 30 μm or less may be 80% or more of all the fillers.

The content of the filler (in particular, the inorganic filler), for example, may be 40 to 300% by mass on the basis of the total mass of the components other than the filler in the thermosetting resin composition 12.

In order for preservation stability, electromigration prevention, and corrosion prevention of a metal conductor circuit, the thermosetting resin composition may contain an antioxidant. Examples of the antioxidant include a benzophenone-based antioxidant, a benzoate-based antioxidant, a hindered amine-based antioxidant, a benzotriazole-based antioxidant, or a phenolic antioxidant. From the viewpoint of the addition effect, the heat resistance, the cost, and the like, the content of the antioxidant may be 0.01 to 10% by mass on the basis of the total mass of the components other than the inorganic filler in the thermosetting resin composition 12.

The dielectric constant at 10 GHz of the cured material of the thermosetting resin composition 12 may be 3.0 or less, or may be 2.8 or less from the viewpoint of being capable of further improving the reliability of an electric signal. The dielectric dissipation factor at 10 GHz of the cured material of the thermosetting resin composition 12 may be 0.005 or less. The dielectric constant can be measured by using a test piece with a height of 60 mm, a width of 2 mm, and a thickness of 300 μm, which is the cured material of the thermosetting resin composition.

The test piece may be vacuum-dried at 30° C. for 6 hours before measurement. The dielectric dissipation factor can be calculated from a resonance frequency obtained at 10 GHz and an unloaded Q value. The measurement device may be a vector network analyzer E8364B manufactured by Keysight Technologies, and CP531 (10 GHz resonator) and CPMAV2 (program) manufactured by Kanto Electronics Application Development Co., Ltd. The measurement temperature may be 25° C.

The glass transition temperature of the cured material formed by thermosetting the thermosetting resin composition 12 may be 120° C. or higher from the viewpoint of suppressing a crack during a temperature cycle, or may be 140° C. or higher from the viewpoint of being capable of relaxing a stress to the wiring. The glass transition temperature of the cured material may be 240° C. or lower from the viewpoint of being capable of performing lamination at a low temperature, or may be 220° C. or lower from the viewpoint of being capable of suppressing curing shrinkage.

The width of the prepreg 1, for example, may be 200 to 1300 mm. The thickness of the prepreg 1, for example, may be 15 to 300 μm. In a case where the thickness of the prepreg 1 is less than 15 μm, there is a tendency that irregularities derived from the inorganic fiber base material 11 remain and the flatness relatively decreases. In a case where the thickness of the prepreg 1 is greater than 300 μm, there is a tendency that the warping increases.

The prepreg 1, for example, can be obtained by a method including impregnating a resin varnish containing the thermosetting resin composition 12 and a solvent in the inorganic fiber base material 11, and removing the solvent from the resin varnish.

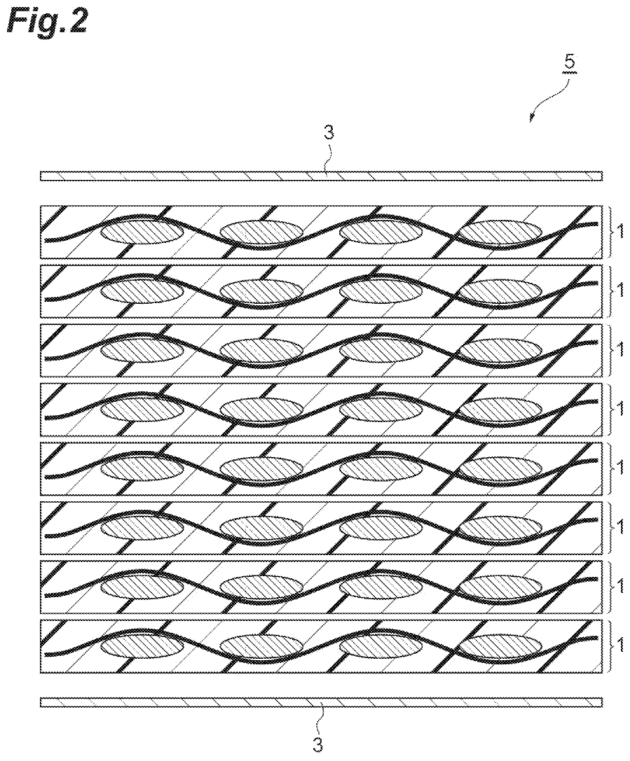

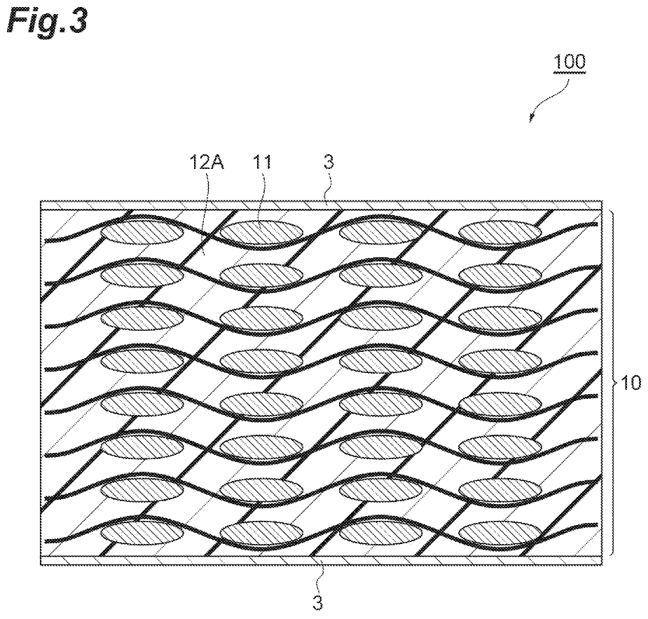

FIG. 2 and FIG. 3 are sectional views illustrating an example of a method for manufacturing the substrate material for a semiconductor package. The method illustrated in FIG. 2 and FIG. 3 includes a step of increasing the temperature of the laminated body 5 in which a metal foil 3, two or more prepregs 1, and a metal foil 3 are laminated in this order to a hot-press temperature while pressurizing the laminated body 5, and a step of heating the laminated body 5 at a temperature higher than or equal to the hot-press temperature while pressurizing the laminated body 5 in a thickness direction thereof to form a substrate material 100 for a semiconductor package including an insulating substrate 10 formed by integrating two or more prepregs 1, and the metal foil 3 provided on both surfaces of the insulating substrate 10, in this order.

In the step of increasing the temperature of the laminated body 5 to the hot-press temperature while pressurizing the laminated body 5, the laminated body 5 is heated in a heating condition where the lowest melt viscosity of the prepreg 1 is 5000 Pa·s or less or 4000 Pa·s or less. According to the hot-press method including such a temperature increase process, it is possible to easily manufacture the substrate material 100 for a semiconductor package with a small thickness variation. By using the substrate material 100 for a semiconductor package, it is possible to manufacture a semiconductor device transmitting a high-frequency signal, in which fine wiring is formed and a chip including a fine bump is connected, with high reliability and high productivity. The substrate material 100 for a semiconductor package to be obtained is also excellent in the reduction of the warping. Here, the heating condition is a condition relevant to a temperature profile, and may include a temperature increase rate, and a retention temperature and a retention time in a case where the laminated body 5 is retained at a predetermined retention temperature. The temperature increase rate may be constant, or may vary.

In the step of increasing the temperature of the laminated body 5 to the hot-press temperature while pressurizing the laminated body 5, the laminated body 5 may be heated in a condition where the lowest melt viscosity of the prepreg 1 is 1000 Pa·s or more 5000 Pa·s or less, or 1000 Pa·s or more 4000 Pa·s or less. In a case where the lowest melt viscosity of the prepreg 1 in the temperature increase process is 1000 Pa·s or more, the thickness variation of the substrate material 100 for a semiconductor package tends to be further reduced.

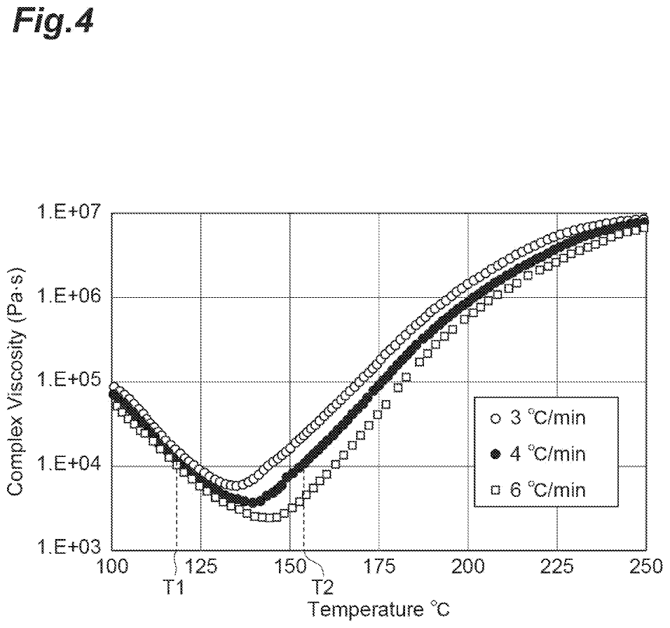

In the step of increasing the temperature of the laminated body 5 to the hot-press temperature while pressurizing the laminated body 5, the melt viscosity of the prepreg 1 decreases to the lowest melt viscosity, and then, increases in accordance with the progress of the curing reaction. FIG. 4 is a graph illustrating an example of a measurement result of the melt viscosity of the prepreg. FIG. 4 is a graph illustrating a relationship between the melt viscosity (complex viscosity) of the prepreg and a temperature, and indicates a melt viscosity measured at a temperature increase rate of 3° C./minute, 4° C./minute, or 6° C./minute for the same prepreg. As exemplified in FIG. 4, in general, in a case where the temperature increase rate is high, the lowest melt viscosity of the prepreg 1 tends to decrease. The temperature increase rate in the step of increasing the temperature of the laminated body 5 to the hot-press temperature while pressurizing the laminated body 5, for example, may be 2° C./minute or more, 3° C./minute or more, or 4° C./minute or more, and may be 8° C./minute or less, 7° C./minute or less, or 6° C./minute or less.

In the step of increasing the temperature of the laminated body 5 to the hot-press temperature while pressurizing the laminated body 5, when the melt viscosity of the prepreg decreases to 10000 Pa·s at the temperature T1 [° C.] in accordance with an increase in the temperature of the laminated body, and then, increases to 10000 Pa·s at the temperature T2 [° C.] through the lowest melt viscosity, the difference between T1 and T2 may be 20° C. or higher. T1 and T2 in FIG. 4 are T1 and T2 when the temperature increase rate is 4° C./minute. From the viewpoint of further suppressing and the like the variation in the wiring width, the difference between T1 and T2 may be 20° C. or higher, or 25° C. or higher, and may be 50° C. or lower.

In the step of increasing the temperature of the laminated body 5 to the hot-press temperature while pressurizing the laminated body 5, the temperature of the laminated body 5, for example, is increased to the hot-press temperature starting from a temperature in a range of 20° C. to 120° C.

In the step of increasing the temperature of the laminated body 5 to the hot-press temperature while pressurizing the laminated body 5, the temperature at which the prepreg 1 exhibits the lowest melt viscosity may be 80° C. or higher, or 120° C. or higher, and may be 200° C. or lower, or 180° C. or lower.

The step of increasing the temperature of the laminated body 5 to the hot-press temperature while pressurizing the laminated body 5 may include increasing the temperature of the laminated body 5 to the retention temperature lower than the hot-press temperature within a range of a temperature ±20° C. at which the prepreg 1 exhibits the lowest melt viscosity, retaining the laminated body 5 at the retention temperature for 5 to 90 minutes, and increasing the temperature of the laminated body 5 from the retention temperature to the hot-press temperature, in this order. During such a process, in general, the laminated body 5 is continuously pressurized.

The substrate material 100 for a semiconductor package is formed by a hot-press that further heats and pressurizes the laminated body 5 of which the temperature increases to the hot-press temperature to a temperature higher than or equal to the hot-press temperature. While heating and pressurizing the laminated body at the temperature higher than or equal to the hot-press temperature, the curing reaction of the thermosetting resin composition in the prepreg 1 progresses, the insulating substrate 10 including an insulating resin layer 12A that is the cured material of the thermosetting resin composition, and the inorganic fiber base material 11 arranged in the insulating resin layer 12A is formed. The hot-press temperature, for example, may be 100° C. to 250° C., or 150° C. to 300° C. A heating and pressurizing time after the temperature increase, for example, may be 0.1 to 5 hours. The substrate material 100 after heating and pressurizing may be further heated, as necessary. The content of the insulating resin layer 12A in the insulating substrate 10 is substantially the same as the content of the thermosetting resin composition 12 in the prepreg 1, and for example, may be 40 to 80% by mass on the basis of the mass of the insulating substrate 10.

From the temperature increase to the heating and pressurizing at the hot-press temperature, in general, the laminated body 5 is continuously pressurized. From the temperature increase to the heating and pressurizing at the hot-press temperature, a pressure to be applied to the laminated body 5, for example, may be 0.2 to 10 MPa.

The metal foil 3 may contain copper, gold, silver, nickel, platinum, molybdenum, ruthenium, aluminum, tungsten, iron, titanium, chromium, or an alloy containing at least one type of such metal elements, from the viewpoint of conductive properties. The metal foil 3 may be a copper foil or an aluminum foil, or may be a copper foil.

A device for heating and pressurizing the laminated body 5, for example, may be a multiplaten press, a multiplaten vacuum press, continuous molding, or an autoclave molding machine.

In a case where the inorganic fiber base material 11 configuring the prepreg 1 is the woven cloth containing the inorganic fiber, two or more prepregs may be laminated such that the directions of the inorganic fibers are aligned, or may be laminated such that the directions of the inorganic fibers are at a right angle.

In the hot-pressing for forming the substrate material for a semiconductor package, a metal plate may be arranged on the surface of the metal foil 3 on a side opposite to the prepreg 1. The thickness of the metal plate may be 0.5 mm to 7 mm. In a case where the thickness of the metal plate is less than 0.5 mm, there is a possibility that the metal plate is easily moved. In a case where the thickness of the metal plate is greater than 7 mm, there is a possibility that handleability decreases. The metal plate, for example, may be a stainless steel plate.

The standard deviation of the thickness measured on any number of spots in an area with any size in the metal plate may be 4 μm or less. In a case where the thicknesses of the metal plate when measured on any n spots are respectively set to T₁, T₂, . . . , Tₙ, and the average thickness of the metal plate is set to T, the standard deviation of the thickness of the metal plate, for example, can be obtained from the following expression.

$$σ = \sqrt{\frac{1}{n} {\sum }_{i = 1}^{n} {( {T}_{i} - T )}^{2}}$$

In the hot-pressing for forming the substrate material for a semiconductor package, a cushion material may be arranged on the surface of the metal foil 3 on a side opposite to the prepreg 1. The cushion material, for example, may be a paper material with a thickness of approximately 0.2 mm. Both of the cushion material and the metal plate may be used.

The hot-pressing for forming the substrate material for a semiconductor package may be performed in a plurality of stages. For example, the method for manufacturing the substrate material for a semiconductor package may further include a step of laminating one or more additional prepregs on the insulating substrate formed by the first hot-pressing to form the second laminated body, and a step of forming an insulating substrate after the second lamination, including a portion containing the additional prepreg, by hot-pressing including increasing the temperature of the second laminated body while pressurizing the second laminated body. In this case, the additional prepreg may also contain the inorganic fiber base material, and the thermosetting resin composition impregnated in the inorganic fiber base material. The content of the thermosetting resin composition may be 40% by mass or more and 80% by mass or less on the basis of the mass of the additional prepreg. The additional prepreg may be the same as or different from the prepreg configuring the laminated body in the first hot-pressing. In the hot-pressing for forming the insulating substrate after the second lamination, the temperature of the second laminated body is increased in a heating condition where the lowest melt viscosity of the additional prepreg is 5000 Pa·s or less. In general, before the additional prepreg is laminated on the insulating substrate, the metal foil is removed from the first laminated body.

In a case where two or more prepregs 1 are used, such prepregs may include two or more types of prepregs with different lowest melt viscosities. In this case, the laminated body 5 is heated in a condition where the maximum value of the lowest melt viscosities exhibited by two or more types of prepregs is 5000 P·s or less. For example, from the viewpoint of reducing the thickness variation of the substrate material for a semiconductor package, the laminated body to be heated and pressurized may include one or more prepregs exhibiting the lowest melt viscosity of 5000 Pa·s or less, and one or more prepregs exhibiting the lowest melt viscosity of 3000 Pa or less, which are arranged on both surface sides.

The width of the substrate material 100 for a semiconductor package may be 200 to 1300 mm from the viewpoint of the productivity. The thickness of the substrate material 100 for a semiconductor package may be 200 to 1500 μμm.

The substrate material 100 for a semiconductor package may have a thickness with a small variation. For example, the standard deviation of the thickness of the substrate material for a semiconductor package may be 4 μm or less, 3.5 μm or less, 3 μm or less, 2.5 μm or less, or 2 μm or less, and may be 0.1 μm or more. The standard deviation of the thickness of the substrate material 100 for a semiconductor package may be a value σ that is calculated from the thicknesses T₁, T₂, . . . , Tₙ of the substrate material 100 for a semiconductor package at each of any n positions by the following expression.

$$σ = \sqrt{\frac{1}{n} {\sum }_{i = 1}^{n} {( {T}_{i} - T )}^{2}}$$

The standard deviation of the thickness of the substrate material 100 for a semiconductor package may be a value determined by a method including dividing the entire main surface of the substrate material for a semiconductor package into a plurality of square areas with one side of 50 mm to measure the thickness on four spots at a position of 2 mm inside from four corners of each area, calculating the value of the standard deviation of the thickness using the values of the thicknesses measured on four spots in each area as a parent population, and setting the maximum value of the values of the standard deviations of the thicknesses calculated in each area to the standard deviation of the thickness of the substrate material 100 for a semiconductor package.

As the position at which the thickness of the substrate material 100 for a semiconductor package is measured, for example, the entire main surface of the substrate material 100 for a semiconductor package is divided into a plurality of regions with an area of 2500 mm², and one or more positions can be selected from each region. The entire main surface of the substrate material 100 for a semiconductor package is divided such that the number of plurality of regions with an area of 2500 mm² is maximized. The thickness is, for example, measured by using a micrometer.

The substrate material 100 for a semiconductor package, for example, can be used as a core material for forming a wiring substrate for a semiconductor package on which a semiconductor chip is mounted. By using the metal foil 3 of the substrate material 100 for a semiconductor package or by removing the metal foil 3 to form wiring on the exposed insulating substrate, it is possible to manufacture a wiring substrate for a semiconductor package including fine wiring.

The wiring substrate for a semiconductor package, for example, can be obtained by a method including forming the wiring on the metal foil 3 with a subtractive method, or a method including forming the wiring with a semi-additive method after the metal foil 3 is removed, as necessary. As necessary, a through hole penetrating through the insulating substrate 10 may be formed, and a conductive via filling the through hole may be formed.

By mounting a semiconductor chip, a memory, and the like at a predetermined position of the wiring substrate for a semiconductor package, the semiconductor package is manufactured. Since the wiring substrate for a semiconductor package obtained by using the substrate material for a semiconductor package according to this embodiment has a small thickness variation, the yield of a step of mounting the semiconductor chip tends to be improved. In addition, a semiconductor chip including a minute solder bump can be more easily mounted on the wiring substrate.

A build-up layer may be formed on the wiring substrate for a semiconductor package. In this case, wiring that is connected to the semiconductor chip can be formed on the build-up layer. A method for forming the build-up layer may be, for example, a subtractive method, a full additive method, a semi-additive method (semi additive process: SAP), a modified semi-additive method (modified semi additive process: m-SAP), or a trench method.

The trench method is a method including forming a build-up material or a photosensitive insulating material layer having a pattern including a groove on the wiring substrate, and filling the groove with a conductive material. The conductive material formed outside the groove is removed by a method such as CMP or a flycutting method. In a case where the thickness variation of the substrate material for a semiconductor package is small, it is possible to easily remove the conductive material formed outside the groove while remaining the conductive material filled in the groove.

### EXAMPLES

Hereinafter, the present invention will be described in more detail with Examples. Here, the present invention is not limited to Examples described below.

1. Preparation of Prepreg

Prepreg A

24 g of silicone diamine (Product Name: “KF-8010”, manufactured by Shin-Etsu Chemical Co., Ltd.), 240 g of bis(4-maleimide phenyl) methane, and 400 g of propylene glycol monomethyl ether were put in a flask provided with a stirrer, a thermometer, and a nitrogen substitution device. The resulting reaction liquid was heated at 115° C. for 4 hours to generate a polyimide resin 1. After that, the reaction liquid was condensed by increasing the temperature to 130° C. at a normal pressure to obtain a polyimide resin solution with a concentration of 60% by mass.

The obtained polyimide resin solution (Polyimide Resin Content: 50 g), an epoxy resin solution in which 40 g of a biphenyl aralkyl type epoxy resin (Product Name: “NC-3000-H”, manufactured by Nippon

Kayaku Co., Ltd.) was dissolved in propylene glycol monomethyl ether, 0.5 g of a curing accelerator (Product Name: “2P4MHZ-PW”, manufactured by SHIKOKU CHEMICALS CORPORATION), silica slurry containing 40 g of a silica filler (Product Name: “SC2050-KNK”, manufactured by Admatechs Company Limited), and N-methyl pyrrolidone were mixed, and the mixture was stirred for 30 minutes to obtain a resin varnish. The total concentration of the polyimide resin and the epoxy resin in the resin varnish was 65% by mass. The obtained resin varnish was impregnated in a glass cloth (a thickness of 0.1 mm) containing an E glass fiber, and was heated and dried at 150° C. for 10 minutes to obtain a prepreg A with a resin content (the content of the thermosetting resin composition) of 50% by mass.

Prepreg B

A prepreg B was prepared as with the prepreg A, except that the resin content was changed to 70% by mass.

Prepreg C 10.3 g of 2,2-bis(4-(4-aminophenoxy)phenyl) propane, 4.1 g of 1,4-butanediol bis(3-aminopropyl) ether (Product Name: “B-12”, manufactured by Tokyo Chemical Industry Co., Ltd.), and 101 g of N-methyl pyrrolidone were put in a flask provided with a stirrer, a thermometer, and a nitrogen substitution device. Next, 20.5 g of 1,2-(ethylene) bis(trimellitate anhydride) was added. The resulting reaction liquid was stirred at a room temperature for 1 hour, and then, a reflux cooler with a moisture receptor was attached to the flask. The temperature of the reaction liquid was increased to 180° C. while blowing out nitrogen gas, and the temperature was retained for 5 hours such that a reaction progressed while removing water to generate a polyimide resin 2. A polyimide resin solution was cooled to a room temperature.

The obtained polyimide resin solution (Polyimide Resin Content: 50 g), an epoxy resin solution in which 40 g of a biphenyl aralkyl type epoxy resin (Product Name: “NC-3000-H”, manufactured by Nippon Kayaku Co., Ltd.) was dissolved in N-methyl pyrrolidone, 0.5 g of a curing accelerator (imidazole compound, Product Name: “2P4MHZ-PW”, manufactured by SHIKOKU CHEMICALS CORPORATION), silica slurry containing 40 g of a silica filler (Product Name: “SC2050-KNK”, manufactured by Admatechs Company Limited), and N-methyl pyrrolidone were mixed, and the mixture was stirred for 30 minutes to obtain a resin varnish. The total concentration of the polyimide resin and the epoxy resin in the resin varnish was 65% by mass. The obtained resin varnish was impregnated in a glass cloth (thickness of 0.1 mm) containing an E glass fiber, and was heated and dried at 150° C. for 10 minutes to obtain a prepreg C with a resin content of 50% by mass.

Prepreg D

A prepreg D was prepared as with the prepreg C, except that the resin content was changed to 70% by mass.

Prepreg E

A prepreg E was prepared as with the prepreg A, except that the resin content was changed to 35% by mass.

Prepreg F

A polyimide solution (Polyimide Content: 50 g) containing the polyimide resin 1, an epoxy resin solution in which 60 g of a biphenyl aralkyl type epoxy resin (Product Name: “NC-3000-H”, manufactured by

Nippon Kayaku Co., Ltd.) was dissolved in propylene glycol monomethyl ether, 1.5 g of a curing accelerator (imidazole compound, Product Name: “2P4MZ”, manufactured by SHIKOKU CHEMICALS CORPORATION), silica slurry containing 50 g of a silica filler (Product Name: “SC2050-KNK”, manufactured by Admatechs Company Limited), and N-methyl pyrrolidone were mixed, and the mixture was stirred for 30 minutes to obtain a resin varnish. The total concentration of the polyimide resin and the epoxy resin in the resin varnish was 65% by mass. The obtained resin varnish was impregnated in a glass cloth (thickness of 0.1 mm) containing an E glass fiber, and was heated and dried at 150° C. for 10 minutes to obtain a prepreg F with a resin content of 50% by mass.

Prepreg G

A prepreg G was prepared as with the prepreg A, except that the resin content was changed to 40% by mass.

Prepreg H

A prepreg H was prepared as with the prepreg A, except that the resin content was changed to 80% by mass.

2. Melt Viscosity of Prepreg

The prepared prepreg was interposed between two parallel plates with a diameter of 8 mm, and the melt viscosity (complex viscosity) of a laminated body was measured at a frequency of 10 Hz in a shear mode in a temperature increase condition of Condition A described below, by using a viscoelasticity measurement device (ARES, manufactured by Rheometric Scientific Far East Ltd.). From measurement results, the lowest melt viscosity was obtained. A temperature T1 [° C.] at a point when the melt viscosity decreased to 10000 Pa°s in accordance with an increase in the temperature, and then, a temperature T2 [° C.] at a point when the melt viscosity increased to 10000 Pa°s through the lowest melt viscosity were obtained, and a difference (T2−T2) between T1 and T2 was calculated. Further, a melt viscosity increase rate per 1 minute while the melt viscosity increased to 1000×10³ Pa·s from a point when the lowest melt viscosity was exhibited was obtained. The melt viscosity of the prepreg A in a case where the temperature increase condition was changed to Condition B or C described below was measured.

The measurement results are shown in Table 1.

Condition A: The temperature is increased to 250° C. from 20° C. at a temperature increase rate of 4° C./minute

Condition B: The temperature is increased to 250° C. from 20° C. at a temperature increase rate of 6° C./minute

Condition C: The temperature is increased to 140° C. from a room temperature (approximately 25° C.) at a temperature increase rate of 6° C./minute, pressurizing is retained at 140° C. for 30 minutes, and then, the temperature is increased to 230° C. from 140° C. at a temperature increase rate of 6° C./minute

A temperature at which the prepreg A exhibited the lowest melt viscosity was 135° C. in Condition A, and was 145° C. in Condition B.

TABLE 1

| | | Prepreg | | | | | | | |
|---|---|---|---|---|---|---|---|---|---|
| | | A | B | C | D | E | F | G | H |
| Polyimide resin 1 | | 50 | 50 | | | 50 | 50 | 50 | 50 |
| Polyimide resin 2 | | | | 50 | 50 | | | | |
| Epoxy resin | | 40 | 40 | 40 | 40 | 40 | 50 | 40 | 40 |
| (NC-3000-H) | | | | | | | | | |
| Curing | 2P4MHZ-PW | 0.5 | 0.5 | 0.5 | 0.5 | 0.5 | | 0.5 | 0.5 |
| accelerator | 2P4MZ | | | | | | 1.5 | | |
| Silica filler | | 40 | 40 | 40 | 40 | 40 | 50 | 40 | 40 |
| Resin content [wt. %] | | 50 | 70 | 50 | 70 | 35 | 50 | 40 | 80 |
| Lowest melt | Condition A | 4500 | 2500 | 2000 | 1500 | 5500 | 7000 | 5000 | 2000 |
| viscosity [Pa · s] | Condition B | 3500 | | | | | | | |
| | Condition C | 3500 | | | | | | | |
| T2 − T1[° C.] | Condition A | 28 | 40 | 45 | 48 | 22 | 15 | 25 | 46 |
| | Condition B | 33 | | | | | | | |
| | Condition C | 20 | | | | | | | |
| Melt viscosity | Condition A | 60 | 110 | 120 | 150 | 50 | 40 | 55 | 125 |
| increase rate | Condition B | 80 | | | 160 | | | | |
| [kPa · s/min] | | | | | | | | | |

3. Preparation of Substrate Material

Any one of the prepregs A to H was cut into the size of a square with one side of 250 mm. Four prepregs after cutting were stacked, and a copper foil (MT18EX-5, manufactured by MITSUI MINING & SMELTING CO., LTD.) was arranged on both surfaces. A laminated body of the prepreg and the copper foil was pressurized at a pressure of 3 MPa and a vacuum degree of 40 hPa while interposing five cushion materials (KS190, manufactured by Oji Paper Co., Ltd.) with a thickness of 0.2 mm, arranged on both sides of the laminated body, by using a press device (MHPC-VF-350-350-3-70, manufactured by Meiki Co., Ltd.).

The temperature of the press device was increased in accordance with Condition A, B, or C described below while performing the pressurizing, and then, the laminated body was heated and pressurized at 230° C. for 2 hours. After that, an end portion with a width of 25 mm along four sides of the laminated body was cut off by using a cut saw to obtain a substrate material including a square main surface with one side of 200 mm. In Table 2, combinations of the prepregs and the temperature increase conditions applied in each Example or Comparative Example are shown.

Condition A: The temperature is increased to 230° C. from a room temperature (approximately 25° C.) at a temperature increase rate of 4° C./minute

Condition B: The temperature is increased to 230° C. from a room temperature (approximately 25° C.) at a temperature increase rate of 6° C./minute

Condition C: The temperature is increased to 140° C. from a room temperature (approximately 25° C.) at a temperature increase rate of 6° C./minute, pressurizing is retained at 140° C. for 30 minutes, and then, the temperature is increased to 230° C. from 140° C. at a temperature increase rate of 6° C./minute

4. Evaluation of Substrate Material

The flatness (thickness variation) of the substrate material, the connectability of a solder bump, the formability of fine wiring, and a variation in a wiring width were evaluated by the following method. Evaluation results are shown in Table 2. The lowest melt viscosity of the prepreg shown in Table 2 is the lowest melt viscosity measured in a temperature increase condition corresponding to the temperature increase condition adopted in each Example or Comparative Example.

Flatness (Thickness Variation)

The main surface of the substrate material was divided into 16 square areas with one side of 50 mm, and the thickness at a position of 2 mm inside from four corners of each area was measured by using a micrometer (ID-C112X, manufactured by Mitutoyo Corporation). A difference between the maximum value and the minimum value of the thicknesses measured on four spots in each of 16 areas was calculated, and the average value of the difference between the maximum value and the minimum value of the thicknesses in 16 areas (average value of difference in thicknesses) was calculated. The value of the standard deviation of the thickness was calculated using the values of the thicknesses measured on four spots in each of 16 areas as a parent population. The maximum value of the standard deviation of the thickness in each of 16 areas was recorded as the standard deviation of the substrate material.

Warping

The substrate material was left to stand on a horizontal stand, and distances between four sides of the substrate material of 200 mm square 25 and the surface of the stand were measured. The maximum value of four measured distances was recorded as the value of the warping of the substrate material.

Connectability of Solder Bump

A substrate material for a test including a square main surface with one side of 50 mm was cut out from the substrate material by dicing. The substrate material was immersed in an aqueous solution of a sulfuric acid with a concentration of 10% by mass for 1 minute. After water washing, a flux agent (SPARKLE FLUX WF-6317, manufactured by SENJU METAL INDUSTRY CO., LTD.) was applied onto the surface of the substrate material. A semiconductor chip including a solder bump was placed on the surface of the substrate material coated with the flux agent, and the semiconductor chip was mounted on the substrate material by heating in a reflow device (SNR-1065GT, manufactured by SENJU METAL INDUSTRY CO., LTD.) of which the highest temperature was set to 260° C. in a nitrogen atmosphere. The semiconductor chip used herein includes a copper pillar with a diameter of 75 μm and a height of 45 μm, and a solder bump (SnAg) with a height of 15 μm provided thereon, and includes a connection terminal arranged at a pitch of 150 μm. The semiconductor chip includes a square main surface with one side of 25 mm, obtained by dicing a silicon wafer (FBW150-00SnAg01JY, manufactured by WALTS CO., LTD.) with a thickness of 725 μm.

The substrate material and the chip mounted thereon was washed by using an ultrasonic washing machine in a condition where a frequency was 45 kHz and a washing time was 10 minutes to remove the flux agent, and then, was dried by heating at 100° C. for 30 minutes. Subsequently, an underfill was injected between the substrate material and the semiconductor chip on a hot plate heated at 110° C., and was further heated at 150° C. for 2 hours to obtain a semiconductor package for evaluation. The sectional surface of each solder bump positioned at four corners of the semiconductor chip in the obtained semiconductor package was observed on 10 spots with a scanning electron microscope to check the connection between the solder bump and the copper foil of the substrate material. For three semiconductor packages prepared by the same procedure, observation was performed on a total of 120 spots. Among them, the ratio of the spots on which the connection between the solder bump and the copper foil of the substrate material was checked was calculated. A case where the ratio was 90% or more was determined as

“A”, and a case where the ratio was less than 90% was determined as “B”.

Formability of Fine Wiring

A substrate material for a test including a square main surface with one side of 50 mm was cut out from the substrate material by dicing. The copper foil was removed from the substrate material by etching that was performed by immersion in an aqueous solution of ammonium persulfate. A photosensitive insulating material (AR5100, manufactured by Hitachi Chemical Company, Ltd.) was applied onto the exposed insulating substrate with a slit coater, and the coating film was dried by heating at 120° C. for 1 minute, and then, was cured by heating at 230° C. for 2 hours in a nitrogen atmosphere to form an insulating resin layer with a thickness of 5 μm. A seed layer including a titanium layer (thickness of 50 nm) and a copper layer (thickness of 150 nm) was formed on the insulating resin layer by sputtering. The layer of a photoresist (RY-5107UT, manufactured by Hitachi Chemical Company, Ltd.) was formed on the seed layer, and a range of 70 mm square of the photoresist was exposed with UV by using a projective exposure device (S6Ck Exposure Machine, manufactured by CERMA PRECISION, INC.). The photoresist after exposure was developed by spraying an aqueous solution of 1% by mass of sodium carbonate using a spin developer (ultra-high pressure spin developing device, manufactured by Blue Ocean Technology., Ltd.). By such exposure and developing, 20 sets of patterns in which 20 linear portions with a height of 400 μm were arranged at resist width/space width=2 μm/2 μm were formed. The surface of the exposed seed layer was treated with oxygen plasma for 1 minute in a condition where an output was 500 W, a pressure was 150 mTorr, and a gas amount was 100 sccm by using Plasma Asher (AP series batch-type plasma treatment apparatus, manufactured by Nordson Advanced Technology (Japan) K.K.). After that, a copper plating with a thickness of 3 μm was formed on the seed layer by a copper electroplating method. The photoresist was peeled off by using an aqueous solution of 2.38% by mass of tetramethyl ammonium hydroxide. The exposed seed layer was washed with an aqueous solution adjusted by mixing a copper etching liquid (WLC-C2, manufactured by MITSUBISHI GAS CHEMICAL COMPANY, INC.) and pure water at a mass ratio of 1:1 at 23° C. for 30 seconds. Subsequently, the seed layer was immersed in an aqueous solution adjusted by mixing a titanium etching liquid (WLC-T, manufactured by MITSUBISHI GAS CHEMICAL COMPANY, INC.) and an aqueous solution of 23% of ammonia at a mass ratio of 50:1 at 23° C. for 10 minutes to remove the copper layer and the titanium layer. According to the operation described above, 20 sets of wirings including 20 linear portions were formed. Among a total of 400 linear portions of the formed wirings, the ratio of the linear portions in which collapse was checked was calculated. A case in which the ratio was 80% or more and 100% or less was determined as “A”, a case in which the ratio was 50% or more and less than 80% was determined as “B”, and a case where the ratio was 0% or more and less than 50% was determined as “C”.

Variation in Wiring Width

Wiring was formed on the substrate as with the evaluation of “formability of fine wiring”, except that resist width/space width was changed to 5 μm/5 μm. The sectional surface of the wiring was observed by using a scanning electron microscope (SU8200 type electron scanning microscope, manufactured by Hitachi High-Tech Co., Ltd.) to measure the width of the wiring on any three spots and to calculate the standard deviation thereof.

TABLE 2

| | | Ex. | | | | | | | | Comp. Ex. | |
|---|---|---|---|---|---|---|---|---|---|---|---|
| | | 1 | 2 | 3 | 4 | 5 | 6 | 7 | 8 | 1 | 2 |
| Prepreg | | A | A | A | B | C | D | G | H | E | F |
| Prepreg | | 50 | 50 | 50 | 70 | 50 | 70 | 40 | 80 | 35 | 50 |
| Resin content | | | | | | | | | | | |
| [wt %] | | | | | | | | | | | |
| Temperature | | A | B | C | A | A | A | A | A | A | A |
| increase condition | | | | | | | | | | | |
| Prepreg | | | | | | | | | | | |
| Lowest melt | | 4500 | 3500 | 3500 | 2500 | 2000 | 1500 | 5000 | 2000 | 5500 | 7000 |
| viscosity [Pa · s] | | | | | | | | | | | |
| T2 − T1[° C.] | | 28 | 33 | 20 | 40 | 45 | 48 | 25 | 46 | 22 | 15 |
| Melt viscosity | | 60 | 80 | | 110 | 120 | 150 | 55 | 125 | 50 | 40 |
| increase rate | | | | | | | | | | | |
| [kPa · s/min] | | | | | | | | | | | |
| Flatness | Average | 4 | 3 | 2 | 2 | 2 | 3 | 5 | 2 | 7 | 8 |
| [μm] | value of | | | | | | | | | | |
| | difference in | | | | | | | | | | |
| | thicknesses | | | | | | | | | | |
| | Standard | 3 | 2 | 1 | 1 | 1 | 2 | 4 | 1 | 5 | 7 |
| | deviation | | | | | | | | | | |

| | | | | | | | | | | |
|---|---|---|---|---|---|---|---|---|---|---|
| Warping [mm] | 1.8 | 0.8 | 0.5 | 0.5 | 1 | 1.2 | 2.8 | 0.4 | 4.2 | 6.2 |
| Connectability | A | A | A | A | A | A | A | A | B | B |
| of solder bump | | | | | | | | | | |
| Formability of | A | A | A | A | A | A | A | A | B | C |
| fine wiring | | | | | | | | | | |
| Standard | 0.8 | 0.4 | 0.2 | 0.2 | 0.3 | 0.4 | 1 | 0.2 | 1.4 | 2.1 |
| deviation of | | | | | | | | | | |
| wiring width | | | | | | | | | | |
| [μm] | | | | | | | | | | |

### REFERENCE SIGNS LIST

1: prepreg, 3: metal foil, 5: laminated body, 10: insulating substrate, 11: inorganic fiber base material, 12: thermosetting resin composition, 100: substrate material for semiconductor package.

1. A method for manufacturing a substrate material for a semiconductor package, comprising:
of increasing a temperature of a laminated body comprising a metal foil, one or more prepregs, and a metal foil, the metal foils and the prepreg being laminated in this order, to a hot-press temperature while pressurizing the laminated body; and
heating the laminated body to a temperature higher than or equal to the hot-press temperature while pressurizing the laminated body to form a substrate material comprising an insulating substrate including the prepreg, and the metal foil provided on both surfaces of the insulating substrate, in this order,
wherein the prepreg contains an inorganic fiber base material, and a thermosetting resin composition impregnated in the inorganic fiber base material, and a content of the thermosetting resin composition is 40 to 80% by mass on the basis of a mass of the prepreg, and
in increasing the temperature of the laminated body to the hot-press temperature while pressurizing the laminated body, the laminated body is heated in a heating condition in which the lowest melt viscosity of the prepreg is 5000 Pa·s or less.

2. The method according to claim 1, wherein the heating condition is a condition in which the lowest melt viscosity of the prepreg is 1000 Pa·s or more and 5000 Pa·s or less.

3. The method according to claim 1,
wherein the heating condition is a condition in which a melt viscosity of the prepreg decreases to 10000 Pa·s at a temperature T1 [° C.] in accordance with an increase in the temperature of the laminated body, and then, increases to 10000 Pa·s at a temperature T2 [° C.] through the lowest melt viscosity, and a difference between T1 and T2 is 20° C. or higher.

4. The method according to claim 3, wherein the heating condition is a condition in which the difference between T1 and T2 is 50° C. or lower.

5. The method according to claim 1,
wherein said of increasing the temperature of the laminated body to the hot-press temperature while pressurizing the laminated body, includes:
increasing the temperature of the laminated body to a retention temperature lower than the hot-press temperature within a range of a temperature ±20° C. at which the prepreg exhibits the lowest melt viscosity;
retaining the laminated body at the retention temperature for 5 to 90 minutes; and
increasing the temperature of the laminated body to the hot-press temperature from the retention temperature, in this order.

6. A prepreg containing:
an inorganic fiber base material; and
a thermosetting resin composition impregnated in the inorganic fiber base material,
wherein a content of the thermosetting resin composition is 40 to 80% by mass on the basis of a mass of the prepreg, and
the lowest melt viscosity of the prepreg measured at a temperature increase rate of 4° C./minute is 5000 Pa·s or less.

7. The prepreg according to claim 6,
wherein a melt viscosity of the prepreg measured at the temperature increase rate of 4° C./minute decreases to 10000 Pa·s at a temperature T1 [° C.], and then, increases to 10000 Pa·s at a temperature T2 [° C.] through the lowest melt viscosity, and a difference between T1 and T2 is 20° C. or higher.

8. The prepreg according to claim 7, wherein the difference between T1 and T2 is 50° C. or lower.

9. (canceled)

10. (canceled)

11. A substrate material for a semiconductor package, comprising
an insulating substrate including an insulating resin layer, and an inorganic fiber base material provided in the insulating resin layer,
wherein a content of the insulating resin layer is 40 to 80% by mass on the basis of a mass of the insulating substrate, and
a standard deviation of a thickness of the substrate material for a semiconductor package is 4 μm or less.

12. The substrate material for a semiconductor package according to claim 11, further comprising a metal foil provided on both surfaces of the insulating substrate.
